(19) United States
(12) Patent Application Publication
(10) Pub. No.: US 2018/0044799 A1
(43) Pub. Date: Feb. 15, 2018

(54) NON-METALLIC COATING FOR STEEL SUBSTRATES AND METHOD FOR FORMING THE SAME

(71) Applicant: MAGNA INTERNATIONAL INC., Aurora (CA)

(72) Inventors: Mathias BELZNER, Cadolzburg (DE); Ralph DOMNICK, Buckenhof (DE); Edward SCHLEICHERT, Sailauf (DE); Darren WOMACK, Windsor (CA)

(21) Appl. No.: 15/554,897

(22) PCT Filed: Mar. 17, 2016
(86) PCT No.: PCT/CA2016/050298

§ 371 Date: Aug. 31, 2017

(30) Foreign Application Priority Data
Mar. 17, 2015 (DE) 102015204802.0
Mar. 17, 2015 (DE) 102015204803.9

(51) Int. Cl. C23C 28/04; C23C 16/34; C23C 16/54; C23C 14/06

(52) U.S. Cl. CPC C23C 28/042; C23C 14/0652; C23C 16/34; C23C 16/54

(57) ABSTRACT

A non-metallic coating for a steel substrate or for a coated steel substrate includes a first layer fabricated from at least one of a silicon oxide, a silicon nitride, and a silicon oxynitride, as well as a second layer fabricated from chromium nitride. The second layer has a thickness between 3 nm and 30 nm, and the first layer and the second layer together form a stacked-layer structure having a total thickness of not more than 300 nm.

### FIELD OF THE INVENTION

The invention relates generally to a non-metallic coating for steel substrates and for coated steel substrates. More particularly, the invention relates to a multi-layer non-metallic coating including at least one protective layer and at least one absorber layer, and to a method and system for forming such a coating on a steel substrate or on a coated steel substrate.

### BACKGROUND

Motor vehicle components are often produced by hot-forming a cold-rolled or hot-rolled steel sheet. Examples of such automotive steel products include vehicle columns, supports, bumpers, rocker panels, fuel tank assemblies, door frames, and components such as parts of the floor of the motor vehicle. Hot-forming is carried out at a temperature greater than 700° C. and often includes hot-stamping the steel sheet. Rapid cooling of the component is then performed in order to improve the mechanical strength and other properties of the finished product.

Unfortunately, uncoated steel substrates are susceptible to scale formation, corrosion and decarburization, which can occur at exposed surfaces of the substrate during hot-forming. These types of surface defects can lead to reduced mechanical strength in the finished product and produce increased wear on the forming tools. Further, these types of surface defects make it more difficult to paint the surface of the component and may lead to poor adhesion of a subsequently applied paint coat.

Various solutions have been suggested for reducing the severity of these types of surface defects. For instance, the hot-formed steel part can be shot-blasted to remove surface corrosion and scaling, but this requires a high degree of energy and may have a negative influence on other properties of the component. Alternatively, the steel substrate may be heated in a controlled atmosphere oven in order to prevent the surface defects from occurring in the first place, but this solution increases the cost and complexity of the system that is used to carry out the hot-forming process. Further alternatively, the steel substrate may be coated prior to being hot-formed. By way of an example, a coating for a steel substrate is disclosed in WO 2013/166429, which includes one to three different layers, each of which is free of metal atoms. The composition of the layers includes at least silicon and carbon, and the total thickness of the coating is not more than about 300 nm.

It would be beneficial to provide a non-metallic coating and method that overcomes at least some of the above-mentioned disadvantages.

### SUMMARY OF EMBODIMENTS

In accordance with an aspect of at least one embodiment, there is provided a non-metallic coating for a steel substrate or for a coated steel substrate, comprising: a first layer comprising at least one of a silicon oxide, a silicon nitride, and a silicon oxynitride; and a second layer comprising chromium nitride, the second layer having a thickness between 3 nm and 30 nm, wherein the first layer and the second layer form a stacked-layer structure having a total thickness of not more than 300 nm.

In accordance with an aspect of at least one embodiment, there is provided a coated steel component, comprising: a steel substrate; a non-metallic coating formed on the steel substrate, comprising: a first layer comprising at least one of a silicon oxide, a silicon nitride, and a silicon oxynitride; and a second layer comprising chromium nitride, the second layer having a thickness between 3 nm and 30 nm, wherein the first layer and the second layer form a stacked-layer structure having a total thickness of not more than 300 nm.

In accordance with an aspect of at least one embodiment, there is provided a method for coating a steel component with a non-metallic coating, comprising: providing a steel substrate or a coated steel substrate; depositing a non-metallic coating on the steel substrate or the coated steel substrate, including a first layer comprising at least one of a silicon oxide, a silicon nitride, and a silicon oxynitride; and a second layer comprising chromium nitride, the second layer having a thickness between 3 nm and 30 nm, wherein the first layer and the second layer form a stacked-layer structure having a total thickness of not more than 300 nm.

In accordance with an aspect of at least one embodiment, there is provided a non-metallic coating for a steel substrate or for a coated steel substrate, comprising: a first layer comprising at least one of a silicon oxide, a silicon nitride, and a silicon oxynitride; and a second layer comprising a metal nitride, the second layer having a thickness between 3 nm and 30 nm, wherein the first layer and the second layer form a stacked-layer structure having a total thickness of not more than 300 nm.

### BRIEF DESCRIPTION OF THE DRAWINGS

FIG. 1 is a simplified cross-sectional diagram showing a first layer structure for a non-metallic coating deposited on a substrate.

FIG. 2 is a simplified cross-sectional diagram showing a second layer structure for a non-metallic coating deposited on a substrate.

FIG. 3 is a simplified cross-sectional diagram showing a first layer structure for a non-metallic coating deposited on a previously coated substrate.

FIG. 4 is a simplified cross-sectional diagram showing a second layer structure for a non-metallic coating deposited on a previously coated substrate.

FIG. 5 is a simplified flow diagram of a method for coating a steel substrate with a non-metallic coating.

FIG. 6a is a simplified block diagram showing a first production system for coating a steel substrate with a non-metallic coating.

FIG. 6b is a simplified block diagram showing a second production system for coating a steel substrate with a non-metallic coating.

FIG. 7 is a simplified cross-sectional diagram showing a first exemplary non-metallic coating system deposited on a substrate.

FIG. 8 is a simplified cross-sectional diagram showing a second exemplary non-metallic coating system deposited on a substrate.

### DETAILED DESCRIPTION

The following description is presented to enable a person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the scope of the invention. Thus, the present invention is not intended to be limited to the embodiments disclosed, but is to be accorded the widest scope consistent with the principles and features disclosed herein. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The term “coating” is used throughout the description and in the appended claims to refer to a stack of individual layers that is formed on a substrate. The substrate may be a “blank” or a “finished component” that is formed from the blank. The substrate may be a bare steel substrate or a previously coated steel substrate, such as e.g. a zinc plated steel substrate. More generally, the previously applied coating may be a metal coating, a metal alloy coating or a non-metallic coating.

The term “layer” is used to describe a deposited structure that performs a desired function within the coating (e.g. protective layer/absorber layer). A layer may consist of a single stratum or plural strata. The term “sub-layer” is used throughout the description and in the appended claims to identify different strata within a layer. In general, each stratum within a layer is fabricated from a different material.

The term “layer thickness” refers to the material thickness of an identified layer within a coating. When a layer comprises a plurality of sub-layers, the term “layer thickness” as applied to that layer means the total thickness of all of the sub-layer thicknesses.

The terms “coating thickness,” “thickness of the coating,” and “total layer thickness” are used interchangeably to refer to the sum of the layer thickness of all layers within a coating.

The term “non-metallic” is used to describe each of the individual layers in a coating. A layer that is described as being “non-metallic” may also be classified as “free of metal,” which means the layer does not include metal atoms. For instance, as discussed below, the protective layer 1 is non-metallic and is also “free of metal.” On the other hand a layer that is described as being “non-metallic” may contain metal atoms, but it does not exhibit any of the properties that are normally associated with a bulk metal material. For instance, a non-metallic layer does not display the high reflectivity, electrical and thermal conductivity, and ductility characteristics that are typical of a bulk metal material. As discussed below, the absorber layer 2 contains metal atoms but is “non-metallic” because the metal atoms are contained in island structures or because the layer is too thin to behave as a bulk metal material. Of course, a coating that contains only “non-metallic” layers is also described as being “non-metallic.” A “non-metallic” coating or layer may contain unavoidable metal atom impurities. Further, the term “non-metallic” is not intended to exclude semimetals or metalloids, such as for instance silicon.

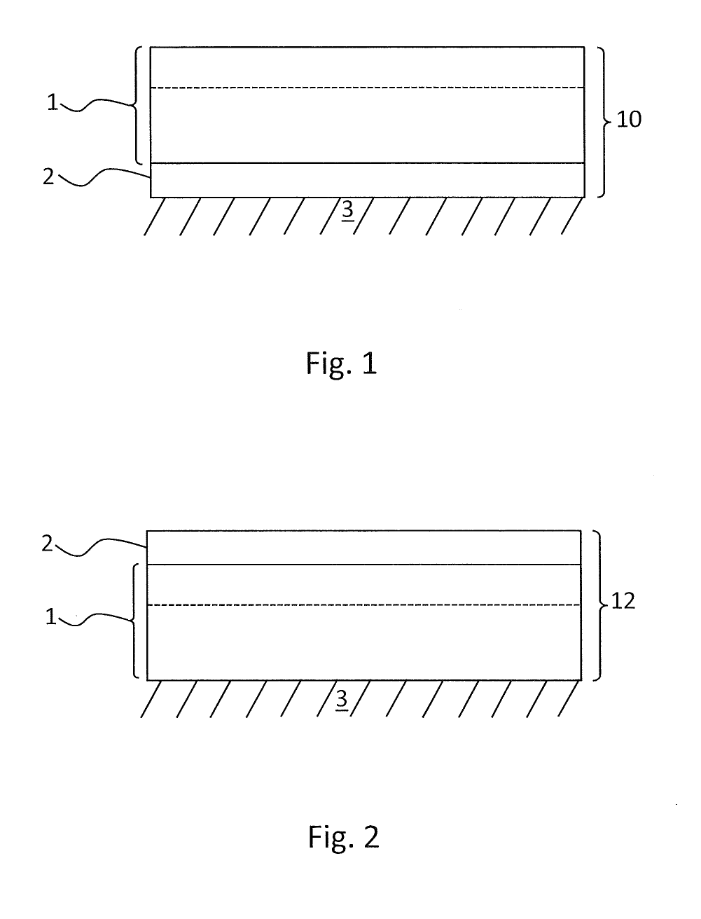

Referring now to FIG. 1, shown is a side cross-sectional view of a non-metallic two-layer coating 10 according to an embodiment of the instant invention. The coating 10 comprises a protective layer 1 and an absorber layer 2, which together form a layered-structure or a stack of layers disposed on a steel substrate 3. In the example that is shown in FIG. 1 the coating 10 is applied directly onto a bare surface of the steel substrate 3. The dashed horizontal line in FIG. 1 denotes an optional sub-layer structuring or stratification within the protective layer 1. In this optional configuration the protective layer 1 comprises a plurality of sub-layers, which collectively provide the protective functionality.

FIG. 2 shows a side cross-sectional view of another non-metallic two-layer coating 12, which also comprises a protective layer 1 and an absorber layer 2, disposed on a steel substrate 3. In the example that is shown in FIG. 2 the coating 12 is applied directly onto a surface of the steel substrate 3. As discussed above with reference to FIG. 1, the dashed horizontal line denotes an optional sub-layer structuring or stratification within the protective layer 1.

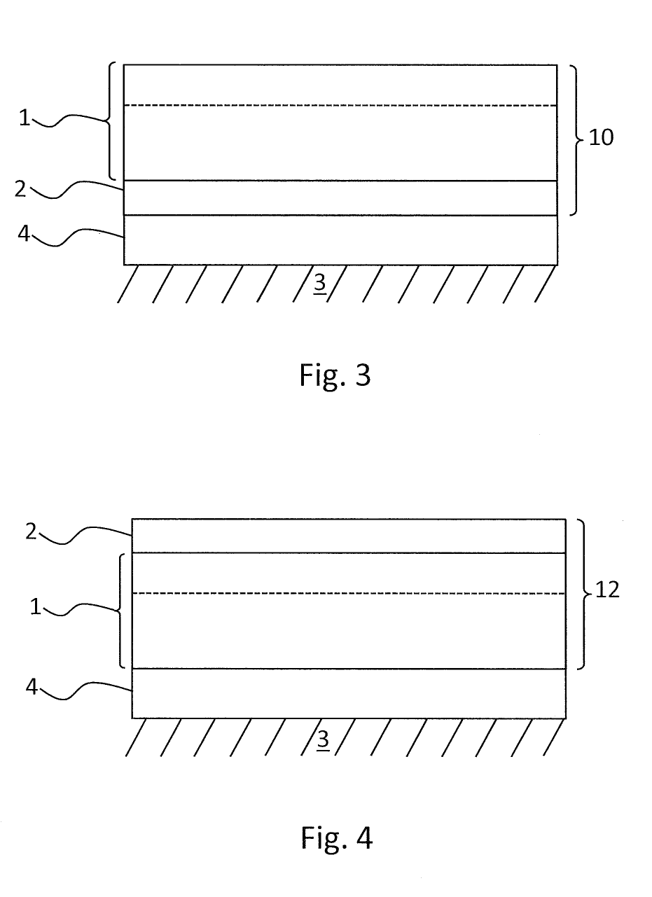

FIGS. 3 and 4 show the same coatings 10 and 12 that are illustrated in FIGS. 1 and 2, respectively, but applied onto a coating 4 that is supported on a surface of the substrate 3. For instance, the coating 4 is a metal alloy layer or a metal plating layer, such as for instance a zinc-plating layer. Optionally, additional not illustrated coating layers are formed between the coating 4 and the substrate 3.

As is apparent, the ordering of the layers 1 and 2 in coating 12 is different than the ordering of the layers 1 and 2 in coating 10, relative to substrate 3. Of course, the layers 1 and 2 in FIGS. 1-2 and the layers 1, 2 and 4 in FIGS. 3-4 are not drawn to scale. In general, it is desirable to form layers 1 and 2 with respective layer thicknesses that are sufficient to exhibit the necessary protection and absorption characteristics, respectively, but that are also thin enough to result in significant savings in cost and time.

Optionally, the layer sequence of the coating 10 or 12 may be repeated one or more times on top of the structures that are shown in FIGS. 1-4, so as to form a thicker coating. For instance, it may be necessary to apply multiple coatings in order to obtain a component with desired properties.

Referring still to FIGS. 1-4, the protective layer 1 is fabricated from at least one of SiOₓ, SiNₓ, and SiOₓN_{y}, where 0≦x≦2 and 0≦y≦1.33, and the absorber layer 2 is fabricated from a metal nitride. In particular, CrN (chromium nitride) has been found to be very well suited for forming the absorber layer 2. CrN is used in manufacturing processes as a hard material layer to increase the useful lifetime of tools, among other things, and can be produced by means of reactive sputtering. This nitrogen compound is characterized by a higher absorption behavior in the wavelength range of 1-3 μm, as compared with iron, and furthermore demonstrates very good physical and chemical resistance. The absorption behavior of CrN in this wavelength range results in quicker and more efficient heating of the substrate during the hot-forming process. Other metal nitrides may also be suitable for forming the absorber layer 2, such as for instance one or more of the group: TiN; AgNₓ; CNₓ; and CuNₓ.

By way of a specific and non-limiting example, the total thickness of the coating 10 or 12 is up to 300 nm. More preferably however the total thickness of the coating is up to no more than about 130 nm. Continuing with the same non-limiting example, the protective layer 1 preferably has a layer thickness of approximately 30-100 nm, and the absorber layer 2 preferably has a layer thickness of approximately 3-30 nm. Of course, the above-mentioned numerical ranges are intended to provide guidance for forming coated steel substrates that are suitable for typical applications encountered in the automotive industry. It is to be understood that some applications may demand coating characteristics that require the deposition of a thicker coating 10 or 12. As already discussed above, a total layer thickness up to about 300 nm is envisaged, but with corresponding reduced savings in cost and time.

Depending on the amount of material (CrN) that is deposited, the absorber layer 2 is applied either in the form of a uniform, thin layer or in the form of island-shaped material clusters. An absorber layer 2 applied in the form of a uniform, thin layer results in a “deck of cards” type structure, in which the protective layer 1 and the absorber layer 2 are distinct layers formed one on top of the other. As a result, there is very little incorporation of the material from one layer into the other layer. On the other hand, an absorber layer 2 that is applied in the form of non-contiguous island-shaped clusters has relatively large interstices between the island-shaped clusters, and these interstices become filled with material of the protective layer 1 when the protective layer 1 is applied to the absorber layer 2 during the formation of the coating.

To optimize the absorption properties of the scale protection layer, “plasmon-based layer paints” are generated. In this connection, island-shaped material clusters play a significant role. The reason for the behavior of metallic island layers lies in the fact that the electrons are freely mobile within the islands, but not between the islands. As the result of a partial and temporary charge shift within the islands, local field intensification occurs, also called plasmon-plasmon interaction. This leads to the result that the electromagnetic radiation is characteristically influenced when passing by this layer. Precisely this influence is absorption intensification, which is implemented in this coating having non-metallic materials. In simplified form, it can be formulated that metallic plasmons are the longitudinal resonance oscillations of the delocalized conduction electrons.

In the case of non-metals, which after all are being used here, what are then involved are the collective oscillations of the valence electrons.

If one applies island-like clusters of the absorber layer 2 to the substrate 3, a very thin layer of about 3 nm is sufficient for achieving the desired properties. Here, too, being metal-free and not integrating the reflective and other characteristic properties of a metal or of an alloy into the layer system is significant.

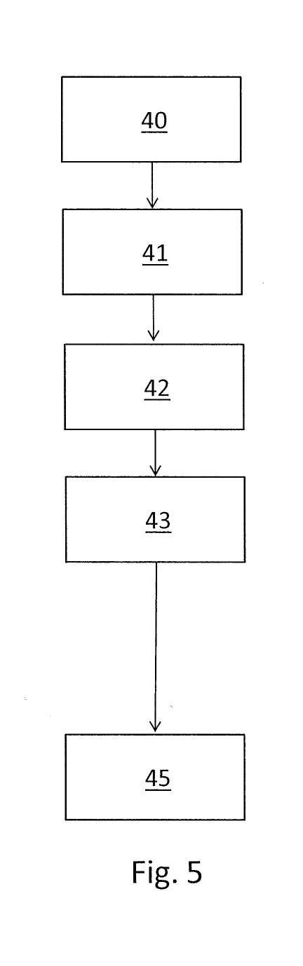

Referring now to FIG. 5, shown is a simplified flow diagram of a method according to an embodiment. An optional preparation step 40, in which the substrate 3 is cleaned, may be performed prior to depositing the coating 10 or 12. The substrate 3 is introduced into a process chamber, a vacuum chamber. Here, in a first process step 41, the surface of the substrate is cleaned using a plasma. Alternatively, cleaning can be omitted. In two consecutive process steps 42 to 43, the layers 1, 2 are deposited onto the substrate 3. By way of a specific and non-limiting example, the protective layer 1 and the absorber layer 2 are formed using sputtering technology. In the last step 45, the substrate is removed from the process chamber.

The coating 10 is obtained when the absorber layer 2 is deposited first, onto the surface of either a bare or previously coated steel substrate. The protective layer 1 is subsequently deposited, either as a single layer or as a plurality of sub-layers.

The coating 12 is obtained when the protective layer 1 is applied first. Applying the protective layer 1 first is practical in order to achieve good adhesion of the thin-layer coating system on the steel substrate 3.

As mentioned above, cleaning the surface to which the coating 10 or 12 is to be applied, using glow discharge, heating or other cleaning of the substrate in a vacuum, is optional. The system for forming such coatings may therefore be simplified, and the cost of such systems is reduced, compared to prior art systems that include components for cleaning the substrate. Beneficially, eliminating the substrate-cleaning step also shortens the production times for forming the coated components. In some cases it is advantageous to carry out the preparation of the steel sheet using plasma cleaning, such as for instance when SiNₓ is used to form the protective layer directly onto the substrate.

Alternatively, the protective layer 1 is formed using Plasma Supported Chemical Vapor Deposition (PE-CVD) and the absorber layer 2 is formed using sputtering technology. Using PE-CVD to form the protective layer 1 results in a coating that demonstrates excellent scale protection characteristics.

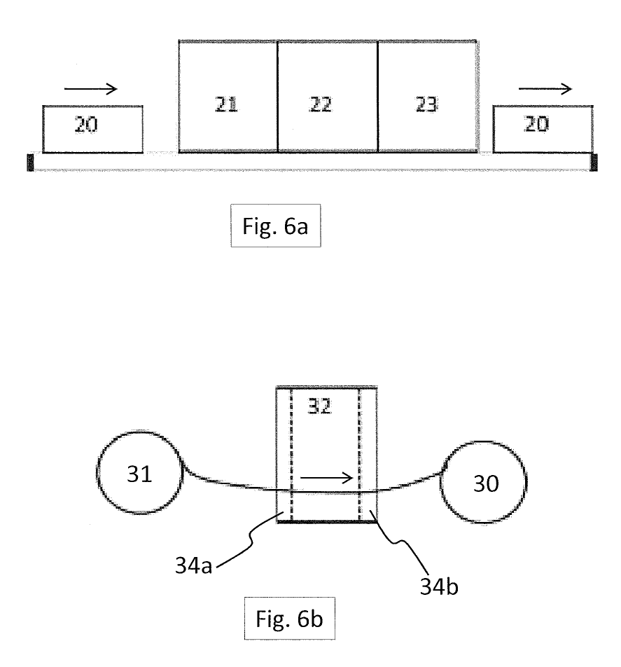

Referring now to FIG. 6a, shown is a simplified block diagram of an in-line system for foaming a coated steel substrate in accordance with an embodiment of the invention. Steel sheets, each having a size of up to approximately 3×6 meters and a thickness of up to approximately 30 mm, are introduced into the system in the form of magazines 20. Depending on the configuration of the particular system, steel sheets of larger or smaller size may be coated. In a specific and non-limiting example, up to 10 sheets lie on top of one another in the magazine 20 and can be supplied to the coating process directly one after the other, using a suitable transfer apparatus, such that the sheets move along a horizontal path that passes under or between sputter targets.

The in-line system comprises at least two vacuum chambers. In the particular system that is shown in FIG. 8a there are three vacuum chambers 21, 22, 23, which are separated from one another by vacuum valves (not shown). A plurality of steel sheets is loaded into a magazine 20, which is then introduced into the first vacuum chamber 21. After a vacuum valve to the outside is closed, the first vacuum chamber 21 is evacuated to a pressure less than 20 mPa. A valve to the second vacuum chamber 22 is then opened, and the magazine 20 is transported into the second vacuum chamber 22. After introduction of the magazine 20 into the second vacuum chamber 22, the valve to the second vacuum chamber 22 is closed, and the first vacuum chamber 21 is ventilated in order to be able to accept the next magazine 20 from the outside. Optionally, when the third vacuum chamber 23 is not present, the first vacuum chamber 21 may be maintained at reduced pressure to support removal of the coated metal sheets from the second vacuum chamber 22.

Referring still to FIG. 6a, the steel sheets are optionally plasma-cleaned in the second vacuum chamber 22 and are coated, directly one after the other, and subsequently stacked flat on top of one another again in the form of a magazine 20. After the coating process is completed the valve to the third vacuum chamber 23 is opened. The magazine 20 with the coated steel sheets is transported into the third vacuum chamber 23, which was previously evacuated to a pressure of 20 mPa or less, and then the valve to the second vacuum chamber 22 is closed. The third vacuum chamber 23 is ventilated, and the magazine 20 with the coated steel sheets is removed to the outside. Of course, if the third vacuum chamber 23 is not present then the coated steel sheets are removed to the outside the same way they were introduced, via the first vacuum chamber 21.

Referring now to FIG. 6b, shown is a simplified block diagram of a roll-to-roll system for forming a coated substrate in accordance with an embodiment. In this case, the steel substrate to be coated is introduced as a strip material and is coated continuously as it passes through the system. Either the entire wound-up steel strip material is situated in a vacuum, or the wind-up unit 30 and unwinding unit 31 for the steel strip are situated outside of the vacuum chamber 32 having the sputter unit(s). The vacuum chamber 32 is designed accordingly. When using a wind-up/unwinding unit 30, 31 outside of the vacuum chamber 32, the steel strip material is introduced and discharged through narrow air locks 34 having sealing lips (not shown), so that the partial vacuum in the vacuum chamber 32 can be kept low, in an almost stable manner.

As discussed supra the protective layer 1 and absorber layer 2 may be deposited using sputtering technology. In this case the systems that are shown in FIGS. 6a and 6b include at least one sputter module. Optionally the systems are configured such that the steel-strips or steel-plates are fed between two sputter modules (not shown), such that the coating 10 or 12 may be applied simultaneously to the front and back surfaces of the steel-strips or steel-plates. Such a system results in significant cost and time savings.

Alternatively, the protective layer 1 is deposited using PE-CVD and the absorber layer 2 is deposited using sputtering technology. In this case the systems shown in FIGS. 6a and 6b include at least one PE-CVD module and at least one sputter module. Optionally the systems are configured such that the steel-strips or steel-plates are fed between two PE-CVD modules and between two sputter modules, such that the coating 10 or 12 may be applied simultaneously to the front and back surfaces of the steel-strips or steel-plates. Such a system results in significant cost savings. In particular, PE-CVD modules are much less expensive in comparison with sputter sources and power supplies for pulsed DC. Additional savings are realized because the coating time for a SiOₓ layer produced with PE-CVD, having a thickness of 30 nm, for example, is significantly less than the time required to produce a layer by means of sputtering. In the case of the sputter module for the absorber layer 2, the large cost reduction is achieved because the layers to be produced have a thickness of preferably less than 10 nm.

The use of PE-CVD methods brings advantages with it: Activation of the starting compounds in the plasma allows clearly lower temperatures during deposition. In plasma-supported oxide deposition, silane SiH₄ and laughing gas N₂O are used:

3SiH₄+6N₂0→3SiO₂+4NH₃+4N₂

Plasma deposition of silicon oxide from TEOS is also possible:

Si(OC₂H₅)₄→SiO₂+decomposition products

Furthermore, plasma deposition of silicon oxide, utilizing a triode configuration, as in the deposition of plasma nitride, as well, allows adjusting the layer tension. The triode configuration of the plasma reactor is used to better adjust the layer tension. In this way, a high plasma density can be adjusted by way of a high-frequency generator, while acceleration of the ions toward the substrate can be achieved by way of a low-frequency generator.

Alternatively, the protective layer 1 can also be vapor-deposited. For this purpose, SiO₂ is evaporated from crucibles, thermally or by means of an electron beam, while the steel plates or the steel strip move through the “vapor cloud” and are coated with SiO₂ while doing so. The actual coating process takes place in a chamber.

The steel surface to be coated must be kept dust-free and grease-free before the process. All non-stainless steels are possible as steel substrates.

### EXAMPLE I

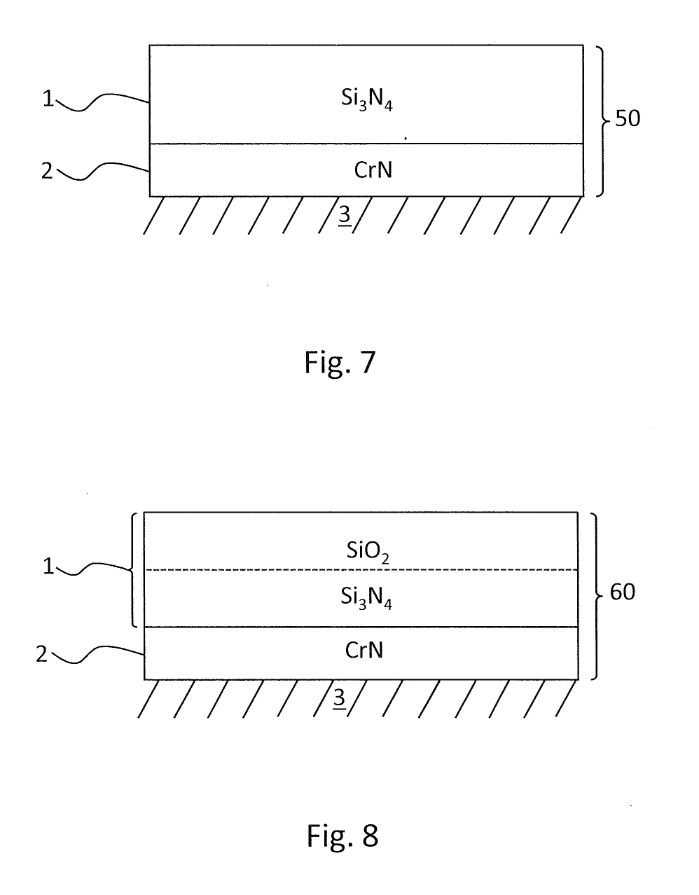

FIG. 7 shows a simplified cross-sectional view of a first exemplary coating 50. The coating 50 comprises a protective layer 1 formed on an absorber layer 2, which in turn is formed on the surface of steel substrate 3. In this example, the absorber layer 2 is fabricated using CrN (chromium nitride) and the protective layer 1 is fabricated using Si₃N₄ (silicon nitride). Non-limiting layer thickness values are CrN=15 nm and Si₃N₄=30 nm. In this example the layer thickness of the Si₃N₄ is sufficiently small that the performance of subsequent electro cathodic coating (E-coating) treatment is not affected. The CrN, which is present with a thickness below 30 nm, shows high absorption in the range between 1 and 3 μm.

### EXAMPLE II

FIG. 8 shows a simplified cross-sectional view of a second exemplary coating 60. The coating 60 comprises a protective layer 1, having two sub-layers, formed on an absorber layer 2, which in turn is formed on the surface of steel substrate 3. In this example, the absorber layer 2 is fabricated using CrN (chromium nitride) and the protective layer 1 is fabricated using Si₃N₄ and SiO₂. The SiO₂ is the topmost sub-layer, and improves paint adhesion during subsequent painting steps. Non-limiting layer thickness values are CrN=17 nm, Si₃N₄=40 nm and SiO₂=12 nm.

More generally, a coating according to an embodiment has the following structure: CrN=17 nm, SiOₓN_{y}=40 nm and SiO₂=12 nm, where 0≦x≦2 and 0≦y≦1.33.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the invent of embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, and/or ordinary meanings of the defined terms. The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases.

Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

Numerical ranges include the end-point values that define the ranges. For instance, “between X and Y” includes both X and Y, as well as all values between X and Y.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The foregoing description of methods and embodiments of the invention has been presented for purposes of illustration. It is not intended to be exhaustive or to limit the invention to the precise steps and/or forms disclosed, and obviously many modifications and variations are possible in light of the above teaching. It is intended that the scope of the invention and all equivalents be defined by the claims appended hereto.

1. A non-metallic coating for a steel substrate or for a coated steel substrate, comprising:
a first layer comprising at least one of a silicon oxide, a silicon nitride, and a silicon oxynitride; and
a second layer comprising chromium nitride, the second layer having a thickness between 3 nm and 30 nm,
wherein the first layer and the second layer form a stacked-layer structure having a total thickness of not more than 300 nm.

2. The non-metallic coating of claim 1 wherein the second layer is formed between the first layer and the substrate.

3. The non-metallic coating of claim 1 wherein the first layer has a thickness between 30 and 100 nm.

4. The non-metallic coating of claim 1 wherein the total thickness of the stacked-layer structure is not more than 100 nm.

5. The non-metallic coating of claim 1 wherein the second layer is substantially continuous and wherein the thickness of the second layer is substantially uniform.

6. The non-metallic coating of claim 1 wherein the second layer comprises island-shaped clusters.

7. The non-metallic coating of claim 6 wherein the island-shaped structures are noncontiguous and wherein material from the first layer occupies the interstices between the island structures.

8. The non-metallic coating of claim 1 wherein the first layer consists of silicon nitride (Si₃N₄).

9. The non-metallic coating of claim 1 wherein the first layer consists of silicon dioxide (Si0₂) and a silicon oxynitride having the formula SiOₓN_{y}, where 0<x<2 and 0<y<1.33.

10. A coated steel component, comprising:
a steel substrate;
a non-metallic coating formed on the steel substrate, comprising:
a first layer comprising at least one of a silicon oxide, a silicon nitride, and a silicon oxynitride; and
a second layer comprising chromium nitride, the second layer having a thickness between 3 nm and 30 nm,
wherein the first layer and the second layer form a stacked-layer structure having a total thickness of not more than 300 nm.

11. The coated steel component of claim 10 wherein the total thickness of the stacked-layer structure is not more than 130 nm.

12. The coated steel component of claim 10 wherein the total thickness of the stacked-layer structure is not more than 100 nm.

13. The coated steel component of claim 10 wherein the second layer is formed between the first layer and the substrate.

14. The non-metallic coating of claim 10 wherein the first layer consists of silicon nitride (Si₃N₄).

15. The non-metallic coating of claim 10 wherein the first layer consists of silicon dioxide (Si0₂) and a silicon oxynitride having the formula SiOₓN_{y}, where 0<x<2 and 0<y<1-33.

16. The coated steel component of claim 10 wherein the second layer is formed on a previously applied coating on the steel substrate.

17. The coated steel component of claim 16 wherein the previously applied coating is one of a metal layer and a metal alloy layer.

18. The coated steel component of claim 10 wherein the second layer is substantially continuous and wherein the thickness of the second layer is substantially uniform.

19. The coated steel component of claim 10 wherein the second layer comprises island-shaped structures.

20. The coated steel component of claim 19 wherein the island-shaped structures are non-contiguous and wherein material from the first layer occupies the interstices between the island structures.

21. A method for coating a steel component with a non-metallic coating, comprising:
providing a steel substrate or a coated steel substrate;
depositing a non-metallic coating on the steel substrate or the coated steel substrate, including:
a first layer comprising at least one of a silicon oxide, a silicon nitride, and a silicon oxynitride; and
a second layer comprising chromium nitride, the second layer having a thickness between 3 nm and 30 nm,
wherein the first layer and the second layer form a stacked-layer structure having a total thickness of not more than 300 nm.

22. The method of claim 21 wherein the first layer and the second layer are deposited using sputtering technology.

23. The method of claim 21 wherein the first layer is deposited using plasma-supported chemical gas-phase deposition (PE-CVD) and the second layer is deposited using sputtering technology.

24. A non-metallic coating for a steel substrate or for a coated steel substrate, comprising:
a first layer comprising at least one of a silicon oxide, a silicon nitride, and a silicon oxynitride; and
a second layer comprising a metal nitride, the second layer having a thickness between 3 nm and 30 nm,
wherein the first layer and the second layer form a stacked-layer structure having a total thickness of not more than 300 nm.

25. The non-metallic coating of claim 24 wherein the second layer is formed between the first layer and the substrate.

26. The non-metallic coating of claim 24 wherein the second layer consists of chromium nitride.
